(19) United States
(12) Patent Application Publication
(10) Pub. No.: US 2024/0332239 A1
(43) Pub. Date: Oct. 3, 2024

(54) HYBRID BOND INTEGRATION FOR MULTI-DIE ASSEMBLY

(71) Applicant: International Business Machines Corporation, Armonk, NY (US)

(72) Inventors: Nicholas Alexander Polomoff, Hopewell Junction, NY (US); Mukta Ghate Farooq, Hopewell Junction, NY (US); Dale Curtis McHerron, Staatsburg, NY (US); Eric Perfecto, Poughkeepsie, NY (US); Katsuyuki Sakuma, Fishkill, NY (US); SPYRIDON SKORDAS, Troy, NY (US)

(21) Appl. No.: 18/191,950

(22) Filed: Mar. 29, 2023

(51) Int. Cl. H01L 23/00; H01L 21/56; H01L 21/768; H01L 23/31; H01L 23/48; H01L 25/00; H01L 25/065

(52) U.S. Cl. CPC H01L 24/20; H01L 21/561; H01L 21/76898; H01L 23/3128; H01L 23/481; H01L 24/08; H01L 24/19; H01L 24/80; H01L 24/95; H01L 25/0652; H01L 25/50; H01L 2224/08145; H01L 2224/19; H01L 2224/214; H01L 2224/80357; H01L 2224/95

(57) ABSTRACT

A three-dimensional (3D) die architecture is provided. The 3D die architecture includes a first die and a second die. The second die includes multiple interior layers of various types and is hybrid bonded to the first die along a hybrid bond layer. The 3D die architecture further includes oxide liner material extending from an exposed surface of the second die to the hybrid bond layer, a first through-silicon-via (TSV) extending from the exposed surface to a corresponding one of the multiple interior layers and a second TSV extending within the oxide liner material from the exposed surface to the hybrid bond layer.

### BACKGROUND

The present invention generally relates to fabrication methods and resulting structures for semiconductor devices. More specifically, the present invention relates to three-dimensional (3D) hybrid bond integration for a multi-die assembly for power distribution and heat dissipation.

Packaging is one of the final manufacturing processes in the transformation of electronic devices into functional products for end users. Packaging must provide electrical and photonic connections for signal input and output, power input and voltage control. Packaging also provides for thermal dissipation and for the physical protection required for reliability.

In the field of electronic packaging, there has been a recent drive to develop thinner and larger structures. This has led to 3D chip stacks, in which chips or dies are layered on top of one another in a 3D stack with electrical interconnects between layers. This configuration has many benefits, such as providing a designer with the ability to place an increased number of chips in a two (2)-D area with an increased amount of electrical communications between them.

### SUMMARY

Embodiments of the present invention are directed to a three-dimensional (3D) die architecture. A non-limiting example of the three-dimensional (3D) die architecture includes a first die and a second die. The second die includes multiple interior layers of various types and is hybrid bonded to the first die along a hybrid bond layer. The 3D die architecture further includes oxide liner material extending from an exposed surface of the second die to the hybrid bond layer, a first through-silicon-via (TSV) extending from the exposed surface to a corresponding one of the multiple interior layers and a second TSV extending within the oxide liner material from the exposed surface to the hybrid bond layer.

Embodiments of the present invention are directed to a three-dimensional (3D) die architecture package. A non-limiting example of the 3D die architecture package includes a package die, first conductive bumps and a second conductive bump electrically communicative and thermally communicative with the package die, respectively, first and second dies hybrid bonded to one another and each including multiple interior layers of various types, oxide liner material extending through the first and second dies, first through-silicon-vias (TSVs), a second TSV and a heat sink. The first TSVs are electrically communicative with the first conductive bumps and extend from the first conductive bumps and through the second die to a corresponding one of the multiple interior layers. The second TSV is thermally communicative with the second conductive bump and extends within the oxide liner material through the second and first dies. The heat sink is thermally communicative with the second TSV.

Embodiments of the invention are directed to a method of assembling a three-dimensional (3D) die architecture. A non-limiting example of the method includes fabricating a first die, fabricating second dies comprising multiple interior layers of various types, hybrid bonding the second dies to the first die along a hybrid bond layer, extending oxide liner material between the second dies to the hybrid bond layer, extending first through-silicon-vias (TSVs) partially through each of the second dies to respective corresponding ones of the multiple interior layers and extending a second TSV within the oxide liner material between the second dies and to the hybrid bond layer.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a side view of a 3D die architecture in accordance with one or more embodiments of the present invention;

FIG. 2 is a side view of the 3D die architecture of FIG. 1 with a cover and a heat sink outside the cover in accordance with one or more embodiments of the present invention;

FIG. 3 is a side view of the 3D die architecture of FIG. 1 with a cover and a heat sink inside the cover in accordance with one or more embodiments of the present invention;

FIGS. 4A and 4B are schematic top-down and perspective views of a 3D die architecture with memory and logic dies and a row of through-silicon-vias (TSVs) in accordance with one or more embodiments of the present invention;

FIGS. 5A and 5B are schematic top-down and perspective views of a 3D die architecture with memory dies and crisscrossing TSVs in accordance with one or more embodiments of the present invention;

FIG. 6 is a flow diagram illustrating a method of building a 3D die architecture in accordance with one or more embodiments of the present invention; and

FIGS. 7A, 7B, 7C, 7D, and 7F are side views of a 3D die architecture and package at various stages of assembly in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, 3D integration (3DI) is a device system integration method that brings heterogeneous devices together in close proximity so that they function as a homogeneous device. 3DI is different than traditional 2D planar back-end-of-line (BEOL) integration in that 3DI adds an additional dimension, (Z) integration, which allows for more devices from different sources and types to be integrated into the system in close proximity and enables them to function as a unit.

There are many advantages of 3DI. These include increased multi-functionality integration of differing dies (memory, logic circuits, signal components, optoelectronic devices, nano-devices, sensors, etc.) into one assembly, increased and improved device performance, increased device density, reduced form factor and packaging and increased yield and reliability.

Some issues associated with 3DI remain. These include, but are not limited to, the need for increased power distribution and density and the corresponding need for heat dissipation and uniformity.

Turning now to an overview of the aspects of the invention, one or more embodiments of the invention address the above-described shortcomings of the prior art by providing for differently-sized through-silicon-vias (TSVs) to be incorporated into a 3D architecture. These differently-sized TSVs can allow for direct paths through the hierarchy of the 3D architecture to thereby provide faster and shorter direct power distribution paths along with increased heat dissipation.

The above-described aspects of the invention address the shortcomings of the prior art by providing for.

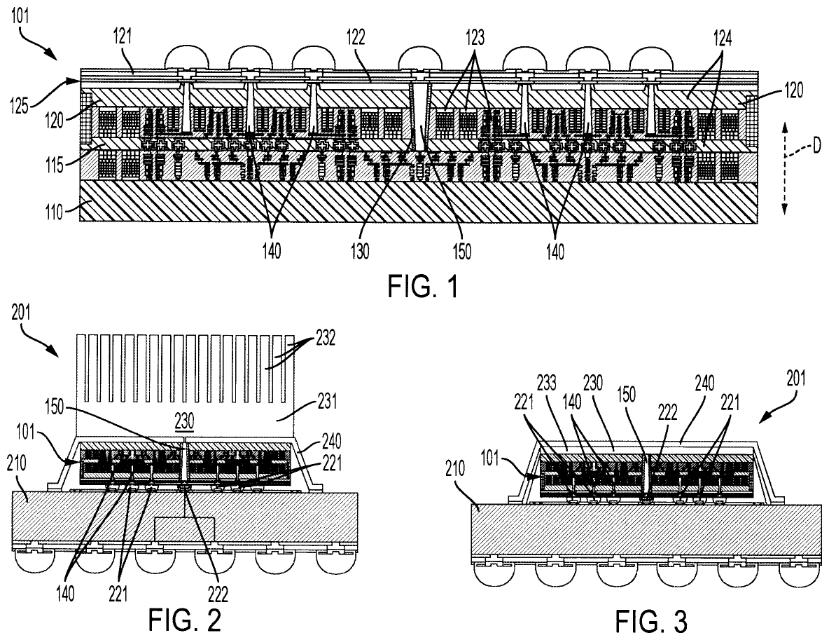

Turning now to a more detailed description of aspects of the present invention, FIG. 1, a 3D die architecture 101 is provided with enhanced power distribution and thermal dissipation capabilities. The 3D die architecture 101 includes a first die 110 and at least one second die 120. The at least one second die 120 can be provided as two or more second dies 120 and the following description will generally relate to the case in which the first die 110 is provided singularly and the second die 120 is provided as two second dies 120. Each of the second dies 120 includes multiple interior layers of various types including, but not limited to, a passivation layer 121, dielectric layers 122, back-end-of-line (BEOL) layers 123 and semiconductor substrate layers 124. The second dies 120 are hybrid bonded to the first die 110 along a hybrid bond layer 115. The first die 110 may have a layered structure similar to that of the second dies 120.

The 3D die architecture 101 further includes oxide liner material 130, a first TSV 140 and a second TSV 150. The oxide liner material 130 can be formed of a thick oxide material, such as low temperature oxide, which can be built into overmold and/or underfill to prevent die damage and degradation. The oxide liner material 130 extends along a thickness direction D of the second dies 120 from an exposed surface 125, which is opposite the hybrid bond layer 115, to the hybrid bond layer 115. The first TSV 140 extends along the thickness direction D of the second dies 120 from the exposed surface 125 to a corresponding one of the multiple interior layers (i.e., one of the BEOL layers 123). The first TSV 140 can be provided as multiple first TSVs 140 and the following description will generally relate to the case in which the first TSV 140 is provided as multiple first TSVs 140 for each of the second dies 120. The second TSV 150 extends along the thickness direction D within the oxide liner material 130 from the exposed surface 125 to at least the hybrid bond layer 115 or further into the first die 110.

As shown in FIG. 1, the second TSV 150 is larger than the first TSVs 140 in multiple dimensions. For example, the second TSV 150 can be longer from top to bottom than any of the first TSVs 140 and can be thicker from side to side than any of the first TSVs 140. In accordance with embodiments, a diameter of the second TSV 150 at its widest height can be about 20-50 μm and at its narrowest height can be about 10-25 μm, a height of the second TSV 150 can be about 150 μm and a pitch of the second TSV 150 can be about 50-100 μm.

With the second TSV 150 extending to at least the hybrid bond layer 115, the second TSV 150 can increase a power distribution to the 3D die architecture 101. In particular, the second TSV 150 can deliver power directly to the hybrid bond layer 115 whereupon the power can be distributed to the various bond pads present in the hybrid bond layer 115 and then to metallization within the first die 110 and the second dies 120.

With reference to FIGS. 2 and 3, the 3D die architecture 101 can be included in a 3D die architecture package 201. In these or other cases, the 3D die architecture 101 can also include a package die 210, first conductive bumps 221 and a second conductive bump 222 by which the first TSVs 140 and the second TSV 150 are electrically communicative with the package die 210, respectively.

In greater detail, the 3D die architecture package 201 can include the package die 210, the first conductive bumps 221 by which the first TSVs 140 are electrically communicative and/or thermally communicative with the package die 210 and the second conductive bump 222 by which the second TSV 150 is electrically communicative and/or thermally communicative with the package die 210. As above, the 3D die architecture package 201 can include the first TSVs 140 and the second TSV 150 and can also include one or more first dies 110 and two or more second dies 120 that are hybrid bonded to one another along hybrid bond layer 115 (see FIG. 1). Each of the one or more first dies 110 and each of the two or more second dies 120 can include the multiple interior layers of various types including, but not limited to, the passivation layer 121, the dielectric layers 122, the BEOL layers 123 and the semiconductor substrate layers 124 (see FIG. 1). The oxide liner material 130 extends along the thickness direction D through or between the one or more first dies 110 and the two or more second dies 120 (see FIG. 1) and a heat sink 230 can be thermally communicative with the second TSV 150 inside or outside a cover 240, which is supportively disposed on the package die 210. As shown in FIG. 2, the heat sink 230 can be provided as a sheet element 231 with multiple fins 232 for heat removal to surroundings. As shown in FIG. 3, the heat sink 230 can be provided as an interposer 233 between the 3D die architecture 101 and the cover 240.

Whereas the second TSV 150 extends to at least the hybrid bond layer 115 in FIG. 1, the second TSV 150 in FIGS. 2 and 3 extends from the second conductive bump 222 through an entire thickness of the 3D die architecture 101 and to the heat sink 230. In this way, the second TSV 150 can increase a heat dissipation capability of the 3D die architecture 101. In particular, the second TSV 150 in these or other cases can draw heat from the entire thickness of the 3D die architecture 101 for delivery and dissipation to the heat sink 230.

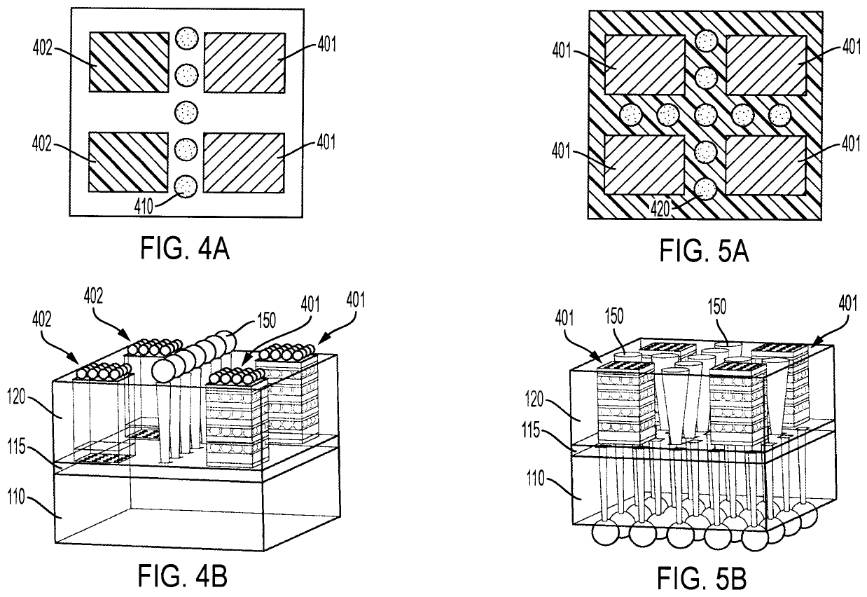

With continued reference to FIG. 1 and with additional reference to FIGS. 4A and 4B and to FIGS. 5A and 5B, each of the second dies 120 can include one or more of a memory die 401 and a logic die 402. In these or other cases, multiple second TSVs 150 can be disposed between the second dies 120 in a row 410 (see FIGS. 4A and 4B) or can be disposed between the second dies 120 in a crisscrossing formation 420 (see FIGS. 5A and 5B).

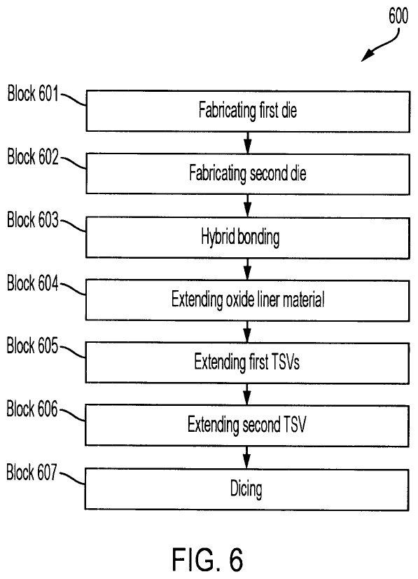

With reference to FIG. 6, a method 600 of assembling a 3D die architecture, such as the 3D die architecture 101 described above, is provided. As shown in FIG. 6, the method 600 includes fabricating a first die (block 601), fabricating second dies, such as memory dies and/or logic dies, which include multiple interior layers of various types (block 602) and hybrid bonding the second dies to the first die along a hybrid bond layer (block 603). The method 600 can further include extending oxide liner material between the second dies to the hybrid bond layer (block 604), extending first TSVs partially through each of the second dies to respective corresponding ones of the multiple interior layers (block 605) and extending one or more second TSV within the oxide liner material between the second dies and to the hybrid bond layer (block 606). In addition, the method 600 can also include dicing the first die from an adjacent first die (block 607). As described above, the first and second TSVs can be electrically and thermally connected to a package die via conductive bumps, a cover can be supportively disposed on the package die and a heat sink can be disposed in thermal communication with the second TSV.

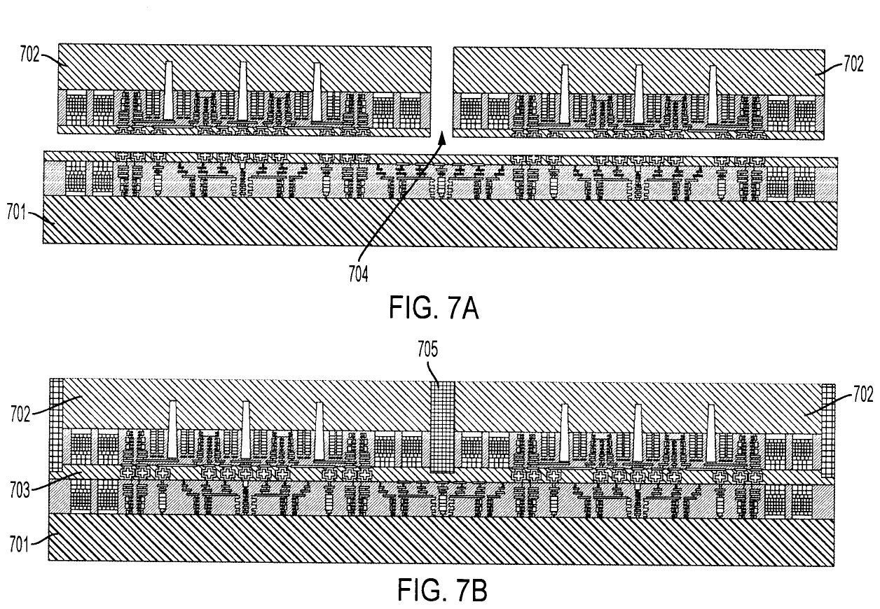

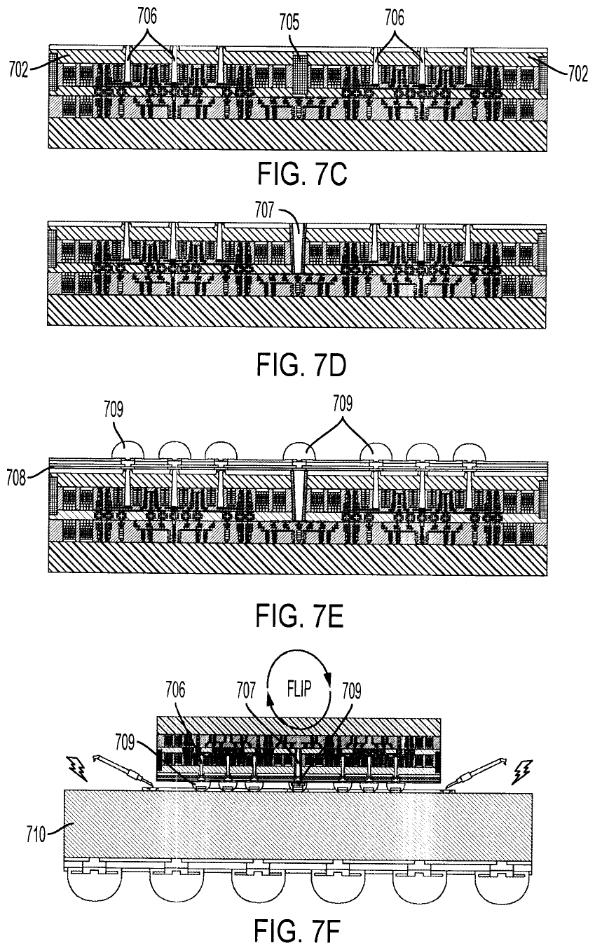

With reference to FIGS. 7A-7F, certain operations of the method 600 of FIG. 6 will now be described in greater detail. As shown in FIG. 7A, the first and second dies 701 and 702 are fabricated and hybrid bonded along hybrid bond line 703 (see FIG. 7B) through heat treatment and annealing processes. This effectively results in the formation of a cavity 704 between the second dies 702. As shown in FIG. 7B, overmold or thick oxide is applied and subject to chemical mechanical polishing and planarization to provide for formation of oxide liner material 705 in the cavity 704. As shown in FIG. 7C. the first TSVs 706, which are formed in at least the second dies 702, are exposed through various polishing, grinding and etching processes. This is followed by the formation of the second TSV 707 within the oxide liner material 705 through various lithographic, etching, depositional and polishing processes as shown in FIG. 7D. As shown in FIG. 7E, dielectric layers 708 are laid down on the second dies 702, the first and second TSVs 706 and 707 are extended outwardly through the dielectric layers 708 and conductive bumps 709 are formed on the first and second TSVs 706 and 707. As shown in FIG. 7F, the first and second TSVs 706 and 707 are electrically and thermally connected with package die 710 via the conductive bumps 709 following dicing and flipping processes and the package die 710 can in turn be coupled with another electronic feature through additional conductive bumps. A cover and a heat sink can be added to complete the 3D die architecture package.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A three-dimensional (3D) die architecture, comprising:
a first die;
a second die comprising multiple interior layers of various types, the second die being hybrid bonded to the first die along a hybrid bond layer;
oxide liner material extending from an exposed surface of the second die to the hybrid bond layer;
a first through-silicon-via (TSV) extending from the exposed surface to a corresponding one of the multiple interior layers; and
a second TSV extending within the oxide liner material from the exposed surface to the hybrid bond layer.

2. The 3D die architecture according to claim 1, further comprising:
a package die; and
conductive bumps by which the first and second TSVs are electrically communicative with the package die.

3. The 3D architecture according to claim 2, further comprising:
a cover supportively disposed on the package die; and
a heat sink disposed in thermal communication with the second TSV.

4. The 3D architecture according to claim 1, wherein the multiple interior layers comprise a passivation layer, dielectric layers, back-end-of-line (BEOL) layers and semiconductor substrate layers.

5. The 3D die architecture according to claim 1, wherein the second TSV is larger than the first TSV in multiple dimensions.

6. The 3D die architecture according to claim 1, wherein:
the second die is provided as two second dies hybrid bonded to the first die along the hybrid bond layer, and
the oxide liner material and the second TSV extending within the oxide liner material are disposed between the two second dies.

7. The 3D die architecture according to claim 6, wherein each of the two second dies comprises one or more of a memory die and a logic die.

8. The 3D die architecture according to claim 6, wherein multiple first TSVs are provided with each of the two second dies.

9. The 3D architecture according to claim 6, wherein multiple second TSVs are disposed between the two second dies.

10. The 3D architecture according to claim 1, wherein:
the second die is provided as multiple second dies hybrid bonded to respective quadrants of the first die along the hybrid bond layer, and
the oxide liner material and the second TSV extending within the oxide liner material are disposed in a crisscrossing formation between the multiple second dies.

11. A three-dimensional (3D) die architecture package, comprising:
a package die;
first conductive bumps and a second conductive bump electrically communicative and thermally communicative with the package die, respectively;
first and second dies hybrid bonded to one another and each comprising multiple interior layers of various types;
oxide liner material extending through the first and second dies;
first through-silicon-vias (TSVs) electrically communicative with the first conductive bumps and extending from the first conductive bumps and through the second die to a corresponding one of the multiple interior layers;
a second TSV thermally communicative with the second conductive bump and extending within the oxide liner material through the second and first dies; and
a heat sink thermally communicative with the second TSV.

12. The 3D architecture package according to claim 11, further comprising a cover supportively disposed on the package die.

13. The 3D architecture package according to claim 11, wherein the multiple interior layers of each of the first and second dies comprise a passivation layer, dielectric layers, back-end-of-line (BEOL) layers and semiconductor substrate layers.

14. The 3D die architecture package according to claim 11, wherein the second TSV is larger than the first TSVs in multiple dimensions.

15. A method of assembling a three-dimensional (3D) die architecture, the method comprising:
fabricating a first die;
fabricating second dies comprising multiple interior layers of various types;
hybrid bonding the second dies to the first die along a hybrid bond layer;
extending oxide liner material between the second dies to the hybrid bond layer;
extending first through-silicon-vias (TSVs) partially through each of the second dies to respective corresponding ones of the multiple interior layers; and
extending a second TSV within the oxide liner material between the second dies and to the hybrid bond layer.

16. The method according to claim 15, further comprising dicing the first die from an adjacent first die.

17. The method according to claim 15, further comprising electrically and thermally connecting the first and second TSVs to a package die via conductive bumps.

18. The method according to claim 15, further comprising:
supportively disposing a cover on the package die; and
disposing a heat sink in thermal communication with the second TSV.

19. The method according to claim 15, wherein each of the second dies comprises one or more of a memory die and a logic die.

20. The method according to claim 15, wherein:
the extending of the oxide liner material between the second dies to the hybrid bond layer comprises extending multiple oxide liner materials between the second dies to the hybrid bond layer; and
the extending of the second TSV within the oxide liner material comprises extending multiple second TSVs within the multiple oxide liner materials.
